(19) United States
(12) Patent Application Publication
(10) Pub. No.: US 2016/0205810 A1
(43) Pub. Date: Jul. 14, 2016

(54) INHERENTLY LEAK FREE LIQUID COOLING OF EQUIPMENT

(71) Applicant: Sam A Marshall, Georgetown, TX (US)

(72) Inventor: Sam A Marshall, Georgetown, TX (US)

(21) Appl. No.: 15/075,814

(22) Filed: Mar. 21, 2016

(51) Int. Cl. H05K 7/20; F28F 27/00; F28D 15/00

(52) U.S. Cl. CPC H05K 7/20272; F28D 15/00; F28F 27/00; H05K 7/20763; F28F 2265/16

(57) ABSTRACT

A system and method of liquid cooling equipment inherently incapable of leaking liquid into the equipment includes maintaining liquid coolant pressure in the vicinity of the equipment below atmospheric pressure. The system and method also includes coolant path defect detection and load balancing.

### TECHNICAL FIELD OF THE INVNETION

This invention relates generally to liquid cooling of electronics and more particularly leak prevention and detection.

### BACKGROUND OF THE INVENTION

Existing electronic equipment cooling systems suffer from a variety of limitations leading to high operating cost, high capital cost, and/or high consequence of failures.

Air cooling suffers from air having a specific heat one fourth that of water, resulting in more energy required for transporting four times the thermal mass from the source to the sink and back. Even with ducting and proper air management, much air is moved across areas that do not require cooling. Improper air management, such as missing blank panels, ducting, or air curtains can create operational issues. Within equipment, components increase the resistance to air flow exactly where it is most needed. Also, very importantly, the low specific heat of air results in an often unacceptably high temperature differential between the equipment and the environment. Every 10 degrees C. of temperature increase approximately shortens the life of electronic equipment by half. This leads to the need for CRAC, chiller, or other air cooling means, and the associated inherent cost and inefficiencies of heat pumps. Fans may fail and require costly and laborious field replacement many times before the electronics will fail. Air carries contaminants, such as dust and dirt, which will eventually accumulate, reducing thermal transfer and increasing air friction of fan blades. The presence of airflow also increases fire hazard and complicates compliance testing.

Due to its higher specific heat and thus higher heat transport efficiency, water cooling is often employed when high-efficiency, high-power density, or long heat transport distances are needed. Unfortunately, pressurized water lines are subject to potentially high negative consequences as a result of failure. Small drips onto non-critical areas can raise humidity levels, leading to corrosion. Drips onto electronics can cause temporary or permanent failure. Leaks in pressurized lines can create spray, causing water damage many meters away from the leak. Larger leaks can create slip hazards or even localized flooding. And, if water is sprayed into high voltage electronics, such as a power supply, breaker panel, or power connector, a potential electrocution hazard may arise.

The advantages of water have motivated hybrid air/water systems, such as employed in a containerized datacenter. Water transfers heat from the container to the environment. But, water fails to make it the last 20 feet. Heat must be transferred from an Integrated Circuit to a heat sink to forced air, then from air to a liquid cooled heat sink.

Oil immersion cooling techniques address some of the drip/spray problems associated with water cooling. However, these systems consist of mausoleums filled with scarcophaghi containing electronics immersed in flammable oil. This is not very compatible with existing racking and operational practices. Simply placing equipment designed to be air cooled into oil dramatically increases floor space as equipment is now stacked horizontally instead of vertically, and the scarcogaphus must be larger than its contents.

Water cooling with pressures below atmospheric pressure have been proposed to address the drip/spray hazards associated with pressurized water. Due to the negative atmospheric pressure, water cannot flow against a pressure gradient and result in a drip or spray hazard. Instead, air will enter the line. This is a much preferred failure mode. However, failures resulting in air ingress into the water lines are still very problematic. Air does not cool as efficiently, resulting in reduced cooling performance. Also, air can cause cavitations in pumps. Leaks must be located and repaired. Finding the source of a leak of air ingress can prove impossibly difficult in a complex system, as there is no obvious puddle to point the way. Another limitation is that flow rates are limited, due to a small pressure differential that can be applied to the system. The maximum pressure is limited by air pressure, which can be substantially reduced at altitude or due to weather. Heat significantly raises the pressure at which a liquid will boil, imposing a minimum useful pressure.

### SUMMARY OF THE INVENTION

According to one embodiment of the invention, electronic equipment is water cooled by an inherently water leak proof system. The pressure of the water within the electronic equipment area is maintained below atmospheric pressure, thereby eliminating the possibility any leak dripping or spraying water, creating a variety of damage and hazards. Any leak at negative pressure will result in air entering the water loop. Air leaks do not leave behind a puddle on the floor, and thus may be extremely difficult to locate, especially in complex datacenter environments with many thousands of opportunities for defects. Air bubbles are easily detected by light scattering. A multitude of sensors reports the location of a leak.

The water pressure in mechanical service areas may be above atmospheric pressure, increasing the useful pressure differential near the electronics. In another embodiment, each Field Replaceable Unit (FRU) has a temperature sensor, flow control valve, and control loop to provide only the necessary amount of water flow needed to maintain the set temperature.

Numerous technical advantages over the state of the art may be realized. A low temperature between IC junction and the environment is achieved, eliminating or almost eliminating the need for very expensive chilling. A high specific heat thermal transfer mass saves energy spent in fluid circulation. Water only flows where it is needed for cooling, saving energy from bad air management practices. Return air aisles are not required, dramatically increasing rack density. Air openings are not needed, a chassis can easily serve as an EMI enclosure and a rated fire enclosure, eliminating the cost and complexity of a fire control system. Also, dust accumulation is of little concern. Liquid leaks and their associated hazards to equipment and personnel are eliminated. Other technical advantages may be readily ascertained by one of skill in the art.

DESCRIPTION OF DRAWINGS

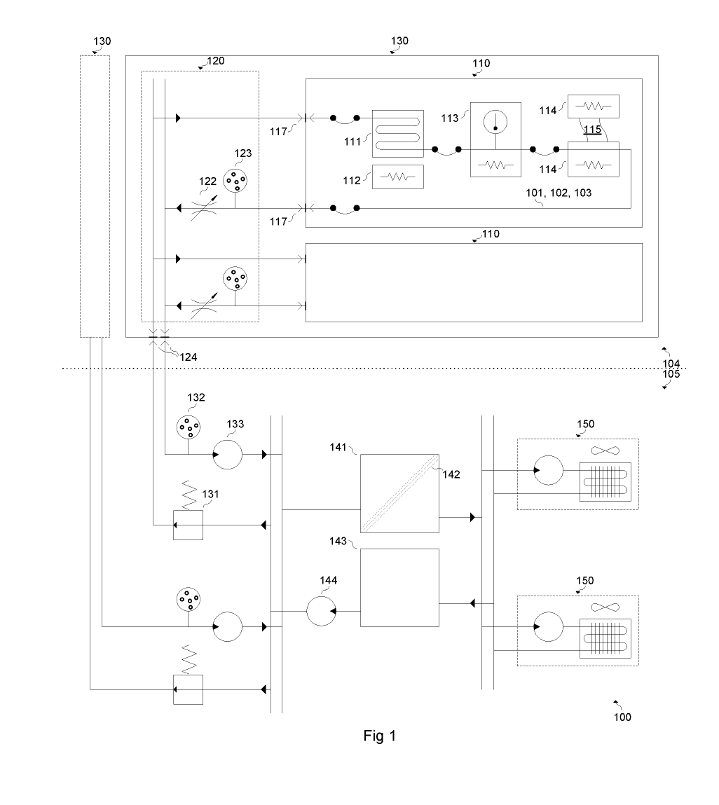

FIG. 1 is a flow diagram of an inherently leak free liquid cooling system.

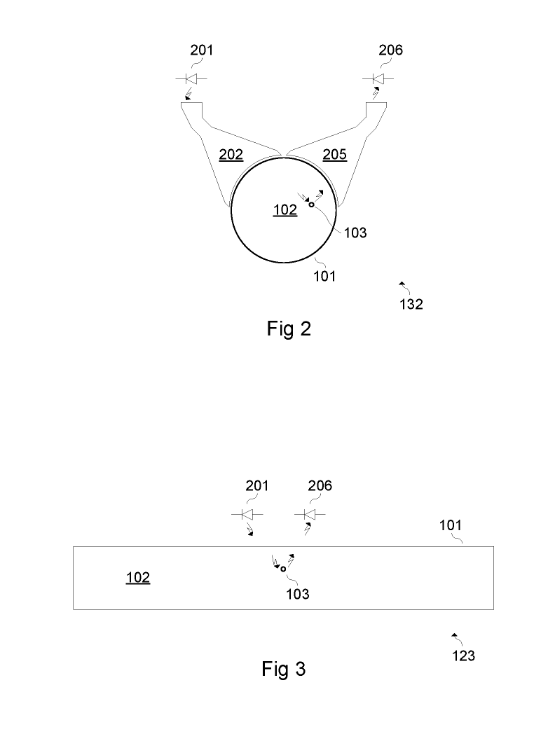

FIG. 2 is a cross section of an air bubble light scattering sensor.

FIG. 3 is a transverse section of an alternate air bubble light scattering sensor.

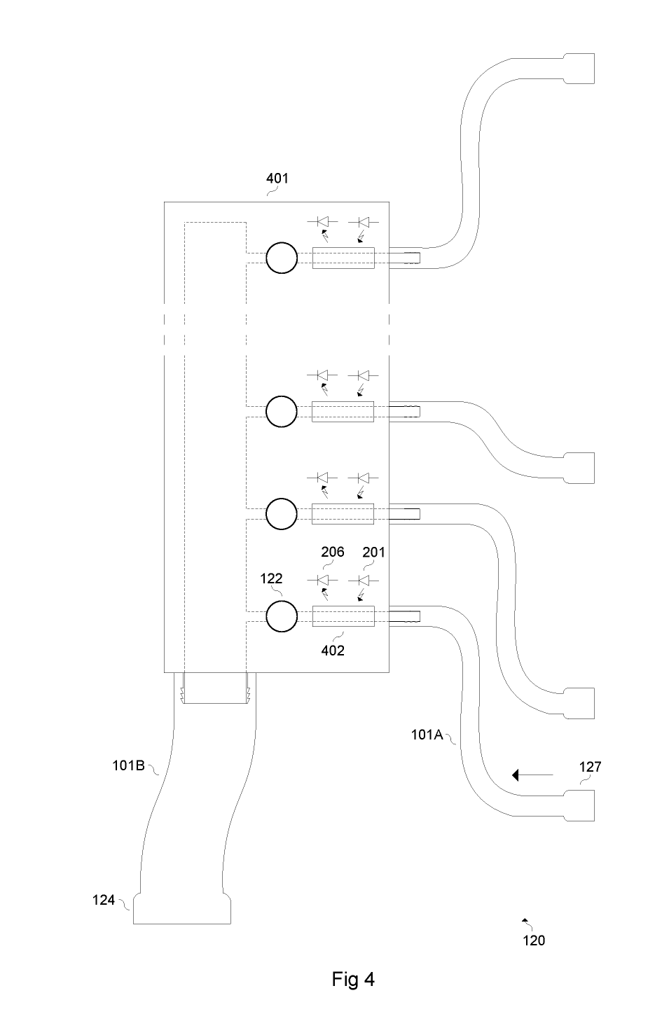

FIG. 4 is a plan view of a return manifold.

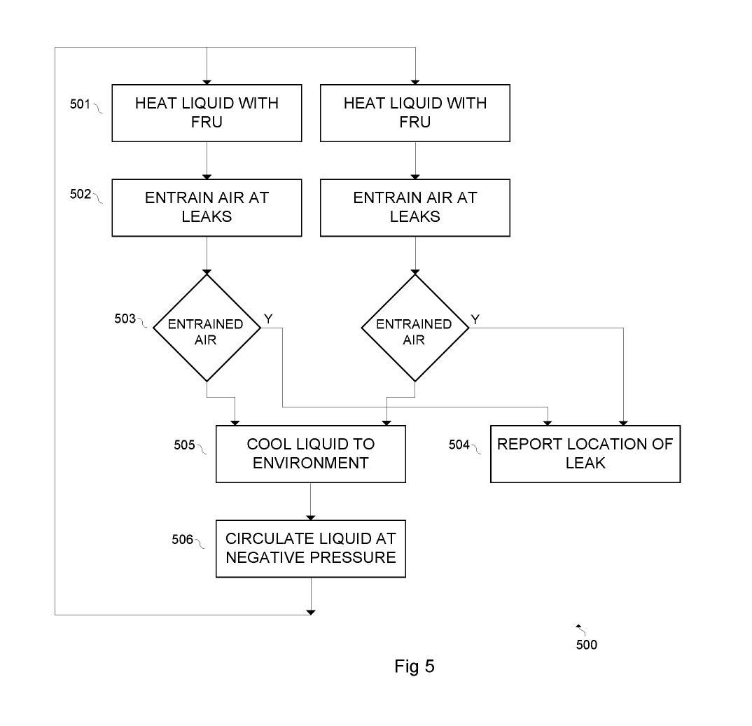

FIG. 5 is a flowchart of an inherently leak free cooling method.

### DETAILED DESCRIPTION

Embodiments of the invention are best understood by referring to FIGS. 1 through 5 of the drawings, like numerals being used for like and corresponding parts of the various drawings.

FIG. 1 is a flow diagram of system 100 associated with leak free liquid cooling of electronics.

A multitude of Field Replaceable Units (FRU) 110 containing electronics and one or more water distribution manifolds 120 are located in a rack 130. A system may include a multitude of racks 130. The terms FRU and rack are used very loosely as any variety of well known hierarchical mechanical packaging arrangements of FRUs or collections of FRUs and includes: shelves, racks, aisles, shipping containers, mobile data centers, containerized data center, equipment rooms, and datacenters. For instance, this could be a card in a shelf, or a containerized data center in a warehouse. Additional distribution manifolds 120 may be arranged in any manner of series/parallel non-redundant/redundant combination as necessary to serve the desired configuration.

FRU 110 may be any variety of heat generating electronic equipment, such as: servers, routers, processors, storage, or blades. FRU 110 may be any other water cooled equipment, such as a vacuum pump, sputter deposition magnetron, or water jacketed vacuum chamber. FRU 110 may contain any variety of heat sources and a liquid path 101. Liquid path 101 contains a cooling liquid 102, and if a leak is present, possibly air bubble 103.

For example, high dissipation heat sources 113 might be one or more of a CPU, GPU, or ASIC and might contain an internal temperature sensor. Liquid path 101 is thermally coupled to the heat source via thermal pad, thermal grease, thermal epoxy, or any other well known means.

High dissipation heat sources 114 might be one or more of an ASIC, FPGA, memory, or power supply component. A multitude of these may have low enough thermal dissipation such that they may be thermally connected with graphite sheet 115 or other thermal conductor and share a single interconnection with liquid path 101. Graphite sheet 115 provides a lower cost means of thermal connecting heat sources 114 than to individually connect each heat source to liquid path 101. Graphite sheet 115 may also thermally connect different component height heat sources and non-planar heat sources, such as transformers and capacitors.

Low dissipation heat sources 112 might be glue logic. These do not dissipate enough heat to cool individually, but collectively generate notable heat. These dissipate heat to air. A cold plate 111 may convectively cool the air within FRU 110. Cold plate 111 may simply be connection of liquid path 101 to the chassis. No fans are required.

In an alternate embodiment, heat sources 112-114 may be non-electronic electrical components, such as pumps, compressors, motors, or vacuum equipment.

Quick connects 117 provide an easy way to insert/remove FRU 110. These may be of the dripless and blind mate variety.

FRU 110 may include an enclosure without any air ventilation. This has several advantages including minimal hydroscopic dust accumulation, minimal exposure to conductive dendrites, much improved EMI performance, and possible fire enclosure. Countless other combinations of heat sources exist.

The supply side of manifold 120 may be a simple fanout. The return side of manifold 120 may include preferably one variable flow restrictor 122 and one bubble detector 123 per FRU 110. Fixed or no flow restrictors are readily envisioned. Alternatively, flow restrictor 122 and/or bubble detector 123 may be located in FRU 110. One manifold may serve an entire shelf. Or, multiple manifolds may be implemented in a 42RU rack. Alternatively, quick connects 117 may also reside on manifold 120, or all components may be implemented discretely with no manifold block.

Variable flow restrictor 122 may be coupled with one or more temperature sensors in FRU 110 and a closed control loop in a manner as to provide only as much coolant flow as required to meet the required component temperatures. This compensates for variations in ambient temperature, pressure, and thermal load. Alternatively, flow restrictor may be provisioned for a minimum flow if FRU 110 is offline, use measured input power to FRU 110 for closed loop control, use an anticipated dissipation, open loop control, or any other manner of controlling or selecting a coolant flow rate.

Liquid path 101 has a large number of connections to a variety of loads, each subject to failure. If a point of failure were allowed to leak cooling liquid into FRU 110, substantial equipment damage or other hazard may result. Liquid 102 is maintained below atmospheric pressure within rack 130. This negative pressure segment of liquid path 101 may extended beyond rack 130 sufficiently such that any potential leak cannot drip, spray, or damage any FRU 110. Alternatively, the liquid pressure may equal or even very slightly exceed atmospheric pressure by an amount sufficiently small such that potential leaks are not able to overcome surface tension. Liquid pressure may be lowered to the minimum allowable for a leak test. A key advantage of negative pressure operation is that any leaks are leaks of air into liquid path 101, forming air bubble 103. Leaks are not of leaking liquid 102 out of liquid path 101. A major drawback of negative pressure is that entrained air reduces cooling, and in sufficient quantities may damage pumps. Furthermore air leaks into any complex system may be very difficult to locate.

Bubble detector 123 detects any air bubbles within liquid path 101. Importantly, this allows determination of the approximate location of a leak.

Quick connects 124 allow easy relocation of shelves, racks, or containers.

For each rack 130, pressure regulator 131 reduces the supply liquid pressure for each rack to a leak-free level, if the pressure supplied by supply pump 144 is above atmospheric pressure. Above atmospheric pressure components are located in a mechanical service area 105, a spray enclosure with a drain, or in any location where leaking liquid would not present a significant hazard. Thus, any above atmospheric pressure components are effectively outside of electronics area 104.

Bubble detector 132 detects any air bubbles returned from rack 130.

The minimum pressure in the system must be maintained sufficiently high as to prevent boiling due to low pressure at any point along liquid path 101. And, the maximum pressure near regulator 131 must be below atmospheric pressure as to prevent any possible leaks. Thus, there is a limited pressure differential to move liquid through FRU 110 in an inherently leak free manner. Return pump 133 may be located as close to rack 130 as possible. Or, if sufficient pressure is available to service multiple racks 130, fewer pumps may be used. Return pump 133 may be variable speed.

De-aeration tank 141 provides a low velocity volume for any air leaked into liquid path 101 to separate. Screens 142 may assist bubbles to coalesce and rise to the surface. Ultrasonics may be used to help release bubbles from screens 142. Tank 141 may also provide thermal storage to allow heat exchanger 150 to be operated at the lowest cost time of day. Also, tank 141 may provide volume for thermal expansion and contraction and a reservoir of liquid to fill any dry FRUs 110 added to the system. Tank 141 may need to be maintained below atmospheric pressure to initially prime liquid path 101.

Storage tank 143 provides thermal storage of cooled water. Supply pump 144 supplies liquid to pressure regulator 131. Supply pump 144 may be variable speed.

Tanks 141 and 143 may be combined as known in the art. Heat exchanger 150 may dissipate heat to the environment in any well known manner. It may be a cooling tower, evaporative cooler, dry heat exchanger, lake, river, or geothermal.

The cooling liquid 102 in liquid path 101 may be water, water with glycol or anti-corrosion additives, oil, or any other suitable heat transfer liquid.

FIG. 2 is an example of a cross section of air bubble light scattering sensor 132. A light source 201 is directed via light pipe 202 through liquid path 101 onto cooling liquid 102. Any air bubble 103 present in liquid 102 will scatter light. Light pipe 205 directs scattered light onto detector 206. Light source 201 may be a LED or a laser. Light detector 206 may be a photodiode. Light pipes 202 and 205 may be any suitable geometry. Light pipes 202 and 205 may include optical fibers. Liquid path 101 may include a translucent polyethylene tube or a vinyl tube.

Any pulses of scattered light at detector 206 are monitored and reported to an operator. The number of pulses is proportional to the number of air bubbles 103. The intensity of the pulses is proportional to the size of air bubbles 103. A steady or increase in the rate of or size of bubbles indicates a probable real leak, due to a breach in liquid path 101. Bubbles may also be present from virtual leaks, due to no fault in liquid path 101. A virtual leak may be due to residual air present due to an incomplete air purge during manufacture or maintenance, or from tiny amounts of air from operating quick connects 117 or 124. A decrease in the rate or size of bubbles indicates a probable virtual leak, especially when correlated with installation or maintenance activities.

Alternatively, instead of monitoring for pulses of light at detector 206, rising or falling edges in intensity level may be monitored. Alternatively, light detector 206 may be positioned to detect transmitted light, with any transient in transmission indicating a bubble.

FIG. 3 is an example of transverse section of an alternate air bubble light scattering sensor 123. Light source 201 and detector 206 may be oriented along the length of fluid path 101. Bubble detector 123 and 132 may be interchanged or selected for size of liquid line 101.

FIG. 4 is a plan view of the return portion of manifold 120. Quick connect 127 and segment of liquid path 101A return liquid 102 from FRU 110. Manifold 401 combines the multitude of return flows. Segment of liquid path 101B and quick connect 124 return liquid 102 from rack 130. In an alternate embodiment to serve a shelf, quick connect 127 is integrated into manifold 401 and manifold 401 is a thermal management backplane, coplanar to the electrical backplane.

Manifold 401 may be injection molded glass reinforced black thermoplastic, bonded sections of tubing, or any other suitable arrangement. Bubble detector 123 may be formed from windows 402 inserted into manifold 401. Alternatively, manifold 401 may be of a translucent or clear material with a geometry selected to reduce optical cross-coupling between separate detectors 123. Light source 201 and light detector 206 monitor for any air bubble 103, if present. Variable flow restrictor 122 may include a tapered pin and an electromagnetic coil, or any other suitable arrangement, driven by a variable electrical current, or other control mechanism.

FIG. 5 is a flowchart of inherently leak free cooling method 500. In step 501, multiple FRUs heat a cooling liquid. In step 502, any leaks in the cooling path allow air ingress into the cooling path. In step 503, any entrained air scatters light and is optically detected. If any leaks are detected, the approximate location of the leak is reported to an operator in step 504. In step 505, heat from the FRU is dissipated to the environment. In step 506, the liquid is circulated at a pressure below atmospheric pressure in the vicinity of the FRUs. The process continues in an infinite loop.

Although the present invention and its advantages have been described in detail, it should be understood that various rearrangements, changes, substitutions, and alterations can be made therein without departing from the spirit and scope of the invention as defined by the appended claims.

What is clamed is:

1. A system for liquid cooling electronics including:
a recirculating liquid coolant within a closed loop coupled to:
an electronic heat source;
an opportunity for a defect in said loop, where said defect will allow air ingress , and form air bubbles within said loop;
an entrained air detector coupled to a means to notify an operator of the presence or absence of entrained air;
a circulation pump;
a heat dissipater; and
a means to maintain the pressure of said coolant within a portion of said loop located near said heat source below atmospheric pressure.

2. The system of claim 1, further including:
a multitude of field replaceable units, each containing at least one said electronic heat source, where said loop passes through said units in a parallel fashion.

3. The system of claim 2, further including:
a multitude of flow rate controllers, each operable to vary the flow of said coolant to each of respective said multitude of field replaceable units.

4. The system of claim 3, where said flow rate controller
is coupled to a temperature detector.

5. The system of claim 3, where said flow rate controller
is coupled to a measurement of input electrical power to said field replaceable unit.

6. The system of claim 2, where
said multitude of field replaceable units are located within a rack and a multitude of said racks within an electronics area; and
the pressure of said liquid within the portion of said loop within said electronics area is maintained below atmospheric pressure and a portion of said loop outside of said electronics area may be maintained above atmospheric pressure.

7. The system of claim 6, where
said electronics area is located within a containerized data center; and
any mechanical area within said containerized data center is housed within a spray enclosure with a drain.

8. The system of claim 2, where
said multitude of field replaceable units are modules located within a shelf; and
the shelf includes a liquid backplane coplanar to an electronics backplane.

9. The system of claim 1, where said entrained air detector includes:
a light source coupled to said coolant such as to illuminate said possible air bubbles entrained within said coolant; and
a light detector coupled to said coolant such as to detect light scattered by said air bubbles.

10. The system of claim 1, where said entrained air detector includes:
a light source coupled to said coolant such as to illuminate said possible air bubbles entrained within said coolant; and
a light detector coupled to said coolant such as to detect light not scattered by said air bubbles.

11. The system of claim 1, where said entrained air detector includes:
a light source coupled to said coolant such as to illuminate said possible air bubbles entrained within said coolant; and
a light detector coupled to said coolant such as to detect a transition in the amount of light either scattered or transmitted by from said coolant.

12. The system of claim 1, further including an air separator.

13. The system of claim 1, further including thermal energy storage.

14. A system for liquid cooling of electronics, including:
a liquid coolant within a closed loop path;
said path includes a multitude of parallel branches, each coupled to corresponding said multitude of electronic units;
a possible defect of said path, where said defect, if present, is operable to allow air to enter said loop and become entrained in said coolant;
a multitude of entrained air sensors coupled to effluent of said coolant from each of said corresponding multitude of electronic units;
each said entrained air sensor includes:
a light source directed to illuminate said coolant, and
a photodiode coupled to said light source and to said coolant as to detect a variation in light level induced by a passing air bubble, if present;
a means to notify an operator of the approximate origin of said entrained air from said possible defect;
a multitude of flow controllers coupled to said coolant from each of said corresponding multitude of units;
each of said multitude of flow controllers operable to respond to: die temperature, measured input power, and/or budgeted input power of said electronics units;
a circulation pump operable to move liquid through said multitude of parallel cooling path branches;
a heat dissipater; and
a means to maintain the pressure of said coolant in a portion of said closed path near said electronics units at a pressure below atmospheric pressure.

15. A method of liquid cooling equipment including:
circulating a cooling liquid through a closed path coupled to said equipment;
maintaining the pressure of said liquid in the vicinity of said equipment below atmospheric pressure;
detecting the presence of any leaks in said cooling path indicated by air in the effluent of said cooling liquid from said equipment; and
automatically reporting said leak to an operator.

16. The cooling method of claim 15, where said air detecting method further includes:
optically illuminating said effluent; and
detecting scattering of said illumination from any said air in said effluent.

17. The cooling method of claim 15, further including:
said cooling path is split into a multitude of branches corresponding to a multitude of said equipment;
monitoring each branch for the presence of any said air, and
notifying an operator which said branch has said leak.

18. The cooling method of claim 15, further including:
limiting the flow in each of said multitude of branches to maintain a set temperature range within said equipment.

19. The cooling method of claim 15, further including:
allowing the pressure of said liquid away from said equipment to be above atmospheric pressure.
